(19) United States
(12) Patent Application Publication
(10) Pub. No.: US 2025/0221194 A1
(43) Pub. Date: Jul. 3, 2025

(54) DISPLAY DEVICE

(71) Applicant: Samsung Display Co., LTD., Yongin-si (KR)

(72) Inventors: Hong Am KIM, Yongin-si (KR); Seung Sue RYU, Yongin-si (KR); Ki Kyung YOUK, Yongin-si (KR)

(21) Appl. No.: 18/789,373

(22) Filed: Jul. 30, 2024

(30) Foreign Application Priority Data
Jan. 2, 2024 (KR) 10-2024-0000323

(51) Int. Cl. H10K 59/131; H10K 59/40; H10K 59/80

(52) U.S. Cl. CPC H10K 59/131; H10K 59/40; H10K 59/873

(57) ABSTRACT

A display device includes: a substrate including a display area in which emission areas are arranged and a non-display area disposed around the display area; a circuit layer on the substrate; an element layer on the circuit layer; an encapsulation layer on the element layer; a touch sensor layer on the encapsulation layer; and a display driving circuit mounted in a part of the non-display area of the substrate. The circuit layer includes a gate insulating layer disposed on the substrate; an interlayer-insulating layer disposed on the gate insulating layer; and a planarization layer disposed on the interlayer-insulating layer. The circuit layer defines a first opening overlapping the display driving circuit and penetrating the planarization layer. The first opening includes a main opening overlapping the display driving circuit, and a first sub-opening extending from a first side, facing the display area, of an edge of the main opening.

This application claims priority to Korean Patent Application No. 10-2024-0000323, filed on Jan. 2, 2024, and all the benefits accruing therefrom under 35 U.S.C. § 119, the content of which in its entirety is herein incorporated by reference.

### BACKGROUND

### 1. Technical Field

The present disclosure relates to a display device.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements, each including a light emitting layer made of an organic light emitting material. As described above, the organic light emitting display device implements image display using a self-light emitting element, and thus may have relatively superior performance in power consumption, response speed, luminous efficiency, luminance, and wide viewing angle compared to other display devices.

One surface of the display device may include a display area in which an image is displayed and a non-display area that is a periphery of the display area. Emission areas emitting light with respective luminances and colors may be arranged in the display area.

### SUMMARY

The display device may include a display driving circuit implemented as an integrated circuit chip.

The display driving circuit may be directly mounted directly on a substrate. In this case, during a process of mounting the display driving circuit, high-temperature and high-pressure stress is applied to an inorganic insulating material and a conductive material of a circuit layer as well as the substrate, which may cause cracks in the inorganic insulating material. The cracks of the inorganic insulating material become a path through which oxygen or moisture permeates, so that oxygen or moisture may cause corrosion of the conductive material or expansion of the organic insulating material. Therefore, disconnection defects and lifting defects are caused, which may drastically reduce the lifespan of the display device.

In view of the above, aspects of the present disclosure provide a display device whose lifespan may be improved by reducing stress at the time of mounting a display driving circuit.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a display device includes: a substrate including a display area in which emission areas are arranged and a non-display area disposed around the display area; a circuit layer disposed on the substrate; an element layer disposed on the circuit layer; an encapsulation layer disposed on the element layer; a touch sensor layer disposed on the encapsulation layer; and a display driving circuit mounted in a part of the non-display area of the substrate. The circuit layer includes a gate insulating layer disposed on the substrate; an interlayer-insulating layer disposed on the gate insulating layer; and a planarization layer disposed on the interlayer-insulating layer. The circuit layer defines a first opening overlapping the display driving circuit in a plan view and penetrating the planarization layer. The first opening includes a main opening overlapping the display driving circuit, and a first sub-opening extending from a first side facing the display area in an edge of the main opening.

A minimum gap between the planarization layer and each of vertices where two sides extending in different directions in the edge of the main opening are connected may be smaller than a minimum gap between the first side of the main opening and the planarization layer in the plan view.

The edge of the main opening may further include a second side facing the first side; and a third side and a fourth side connected between the first side and the second side and facing each other. The planarization layer may include a first protrusion adjacent to a first vertex between the first side and the third side; and a second protrusion adjacent to a second vertex between the first side and the fourth side.

The planarization layer may further include a third protrusion disposed adjacent to a part of the third side and a third vertex between the second side and the third side; and a fourth protrusion disposed adjacent to a part of the fourth side and a fourth vertex between the second side and the fourth side

The first opening may further include a second sub-opening extending from another part of the third side and in contact with the first protrusion and the third protrusion; and a third sub-opening extending from another part of the fourth side and in contact with the second protrusion and the fourth protrusion.

In each of the first protrusion, the second protrusion, the third protrusion, and the fourth protrusion, one side facing the main opening may have an arc shape.

The first opening may further include a second sub-opening extending from the third side and in contact with the first protrusion; and a third sub-opening extending from the fourth side and in contact with the second protrusion.

The display device may further include a circuit board disposed adjacent to the display driving circuit in the plan view and bonded to an edge of the substrate. The circuit layer may further include circuit bonding pads arranged in the main opening and to which the display driving circuit is bonded; circuit connection lines electrically connected to the circuit bonding pads, respectively; and substrate bonding pads arranged side by side on one side of the edge of the substrate adjacent to the circuit bonding pads and to which the circuit board is connected. The circuit bonding pads may include data output pads disposed adjacent to the first side; and data input pads disposed adjacent to the second side. The circuit connection lines may include data supply lines electrically connected to the data output pads, overlapping the first sub-opening, and extending to an edge of the display area; and data pad lines electrically connected to the data input pads and extending to some of the substrate bonding pads.

In a direction in which the first side and the second side face each other, a gap between the first side and the planarization layer may be greater than a gap between the second side and the planarization layer due to a width of the first sub-opening.

In the direction in which the first side and the second side face each other, the gap between the first side and the planarization layer may be within a range from 50 micrometers (μm) to 100 μm.

The planarization layer may include a first planarization layer disposed on the interlayer-insulating layer; and a second planarization layer covering the first planarization layer. The second planarization layer may include a first step portion disposed with a first thickness on the first planarization layer, a bottom extension portion facing the first side and in contact with the interlayer-insulating layer, and a second step portion disposed between the first step portion and the bottom extension portion. A part of the second step portion adjacent to the first step portion may be disposed on the first planarization layer with a second thickness smaller than the first thickness. In the direction in which the first side and the second side face each other, a part of the second step portion of the second planarization layer facing the first side may be disposed with a width greater than the gap between the first side and the planarization layer.

The touch sensor layer may include a touch buffer layer disposed on the encapsulation layer; a touch interlayer-insulating layer disposed on the touch buffer layer; and a touch planarization layer disposed on the touch interlayer-insulating layer. The touch planarization layer may overlap the first step portion in the plan view.

The touch sensor layer may include a touch buffer layer disposed on the encapsulation layer; and a touch interlayer-insulating layer disposed on the touch buffer layer. The circuit layer may further include a lighting circuit overlapping the display driving circuit, surrounded by the main opening, disposed between the data output pads and the data input pads, and covered with the planarization layer. The lighting circuit may be electrically connected to at least some of the data output pads.

Each of the gate insulating layer, the interlayer-insulating layer, the touch buffer layer, and the touch interlayer-insulating layer may contain an inorganic insulating material. The planarization layer may contain an organic insulating material. The touch buffer layer may overlap the lighting circuit and be in contact with the interlayer-insulating layer in the first opening.

The circuit layer may further define a second opening located between the data output pads and the lighting circuit in a direction in which the first side and the second side face each other, extending side by side with the first side, and penetrating at least the touch interlayer-insulating layer among the touch buffer layer and the touch interlayer-insulating layer; and a third opening located between the data input pads and the lighting circuit in the direction in which the first side and the second side face each other, extending side by side with the second side, and penetrating at least the touch interlayer-insulating layer among the touch buffer layer and the touch interlayer-insulating layer.

The circuit layer may further define an auxiliary opening located within the first sub-opening, extending side by side with the first side, and penetrating at least the touch interlayer-insulating layer among the touch buffer layer and the touch interlayer-insulating layer. In a direction in which the first side and the second side face each other, a gap between the auxiliary opening and the planarization layer is smaller than a gap between the auxiliary opening and the first side.

According to an aspect of the present disclosure, a display device includes: a substrate including a display area in which emission areas are arranged and a non-display area disposed around the display area; a circuit layer disposed on the substrate; an element layer disposed on the circuit layer; an encapsulation layer disposed on the element layer; a touch sensor layer disposed on the encapsulation layer; and a display driving circuit mounted in a part of the non-display area of the substrate. The circuit layer includes a gate insulating layer disposed on the substrate; an interlayer-insulating layer disposed on the gate insulating layer; and a planarization layer disposed on the interlayer-insulating layer. The circuit layer defines a first opening overlapping the display driving circuit in the plan view and penetrating the planarization layer. The first opening includes a main opening overlapping the display driving circuit, and a first sub-opening extending from a first side facing the display area in an edge of the main opening. The edge of the main opening further includes a second side facing the first side; and a third side and a fourth side connected between the first side and the second side and facing each other. The planarization layer includes a first protrusion adjacent to a first vertex between the first side and the third side; and a second protrusion adjacent to a second vertex between the first side and the fourth side.

A minimum gap between the first vertex and the planarization layer may be smaller than a minimum gap between the first side and the planarization layer. A minimum gap between the second vertex and the planarization layer may be smaller than the minimum gap between the first side and the planarization layer.

The display device may further include a circuit board disposed adjacent to the display driving circuit in the plan view and bonded to an edge of the substrate. The circuit layer further includes circuit bonding pads arranged in the main opening and to which the display driving circuit is bonded; circuit connection lines electrically connected to the circuit bonding pads, respectively; and substrate bonding pads arranged side by side on one side of the edge of the substrate adjacent to the circuit bonding pads and to which the circuit board is connected. The circuit bonding pads may include data output pads disposed adjacent to the first side; and data input pads disposed adjacent to the second side. The circuit connection lines may include data supply lines electrically connected to the data output pads, overlapping the first sub-opening, and extending to an edge of the display area; and data pad lines electrically connected to the data input pads and extending to some of the substrate bonding pads. The touch sensor layer may include a touch buffer layer disposed on the encapsulation layer; and a touch interlayer-insulating layer disposed on the touch buffer layer. The circuit layer may further include a lighting circuit overlapping the display driving circuit, surrounded by the main opening, disposed between the data output pads and the data input pads, and covered with the planarization layer. The lighting circuit is electrically connected to at least some of the data output pads. Each of the gate insulating layer, the interlayer-insulating layer, the touch buffer layer, and the touch interlayer-insulating layer contains an inorganic insulating material. The planarization layer contains an organic insulating material. The touch buffer layer overlaps the lighting circuit and is in contact with the interlayer-insulating layer in the first opening. The circuit layer may further define a second opening located between the data output pads and the lighting circuit in a direction in which the first side and the second side face each other, extending side by side with the first side, and penetrating at least the touch interlayer-insulating layer among the touch buffer layer and the touch interlayer-insulating layer; and a third opening located between the data input pads and the lighting circuit in the direction in which the first side and the second side face each other, extending side by side with the second side, and penetrating at least the touch interlayer-insulating layer among the touch buffer layer and the touch interlayer-insulating layer.

The circuit layer may further define an auxiliary opening located within the first sub-opening, extending side by side with the first side, and penetrating at least the touch interlayer-insulating layer among the touch buffer layer and the touch interlayer-insulating layer. In the direction in which the first side and the second side face each other, a gap between the auxiliary opening and the planarization layer is smaller than a gap between the auxiliary opening and the first side.

A display device according to embodiments includes a substrate, a circuit layer on the substrate, an element layer on the circuit layer, an encapsulation layer on the element layer, a touch sensor layer on the encapsulation layer, and a display driving circuit. The substrate includes a display area where emission areas are arranged, and a non-display area disposed around the display area. The display driving circuit may be mounted in a part of the non-display area of the substrate. The circuit layer may include a gate insulating layer on the substrate, an interlayer-insulating layer on the gate insulating layer, a planarization layer on the interlayer-insulating layer, and a first opening overlapping the display driving circuit and penetrating the planarization layer. The first opening includes a main opening overlapping the display driving circuit, and a first sub-opening extending from a first side facing the display area in the edge of the main opening.

In this way, the first side of the main opening overlapping the display driving circuit is spaced apart from the planarization layer by the first sub-opening, so that deformation of the organic insulating material of the planarization layer adjacent to the first side due to high-temperature and high-pressure stress during the process of mounting the display driving circuit may be reduced. Hence, crack defects or lifting defects of the inorganic insulating layers disposed around the first side may be reduced, so that disconnection defects or short-circuit defects of wires extending from the first side to the display area may be reduced.

Further, in accordance with embodiments, the edge of the main opening may further include a second side facing the first side, and a third side and a fourth side connected between the first side and the second side and facing each other, and the planarization layer may include a first protrusion adjacent to a first vertex between the first side and the third side, and a second protrusion adjacent to a second vertex between the first side and the fourth side.

In this way, at bent corners facing the display area in the edge of the display driving circuit, the inorganic insulating layers of the circuit layer may be protected by the planarization layer of the organic insulating material, so that lifting defects or corrosion defects may be reduced.

Accordingly, the lifespan of the display device may be improved.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view illustrating a display device according to embodiments;

FIG. 2 is a cross-sectional view taken along line A-A′ of FIG. 1;

FIG. 3 is a layout diagram illustrating part B of FIG. 1;

FIG. 4 is an equivalent circuit diagram showing the light emitting pixel driver of FIG. 3;

FIG. 5 is a plan view illustrating the touch sensor layer of FIG. 2 according to embodiments;

FIG. 6 is an enlarged view showing part C of FIG. 5;

FIG. 7 is a cross-sectional view taken along line D-D′ of FIG. 6;

FIG. 8 is a plan view showing the substrate and the circuit layer of FIG. 2 according to embodiments;

FIG. 9 is a plan view showing part E of FIG. 8 according to one embodiment;

FIG. 10 is a cross-sectional view taken along line F-F′ of FIG. 9;

FIG. 11 is a cross-sectional view taken along line G-G′ of FIG. 9;

FIGS. 12 and 13 are plan views showing part E of FIG. 8 according to embodiments;

FIG. 14 is a cross-sectional view taken along line F-F′ of FIG. 13; and

FIG. 15 is a plan view showing part E of FIG. 8 according to one embodiment.

### DETAILED DESCRIPTION

Advantages and features of the present disclosure and methods of accomplishing the same may be understood more readily by reference to the following detailed description of exemplary embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the present disclosure to those skilled in the art, and the present disclosure will only be defined by the appended claims.

It will be understood that when an element or layer is referred to as being “on” another element or layer, the element or layer can be directly on another element or layer or intervening elements or layers. Like reference numerals refer to like elements throughout the specification. Shapes, sizes, ratios, angles, numbers, etc. disclosed in the drawings for describing embodiments are merely an example, and the present disclosure is not limited to the illustrated details.

It will be understood that, although the terms “first”, “second”, “third”, etc., may be used herein to describe various elements, these elements should not be limited by these terms. These terms are only used to distinguish one element from another element. Thus, a first element discussed below could be termed a second element without departing from the teachings of the present disclosure.

Features of various embodiments of the present disclosure may be partially or entirely coupled to or combined with each other, and may be inter-operated and driven in technically various ways. The embodiments may be implemented independently from each other, or may be implemented together in a co-dependent relationship.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, specific embodiments will be described with reference to the accompanying drawings.

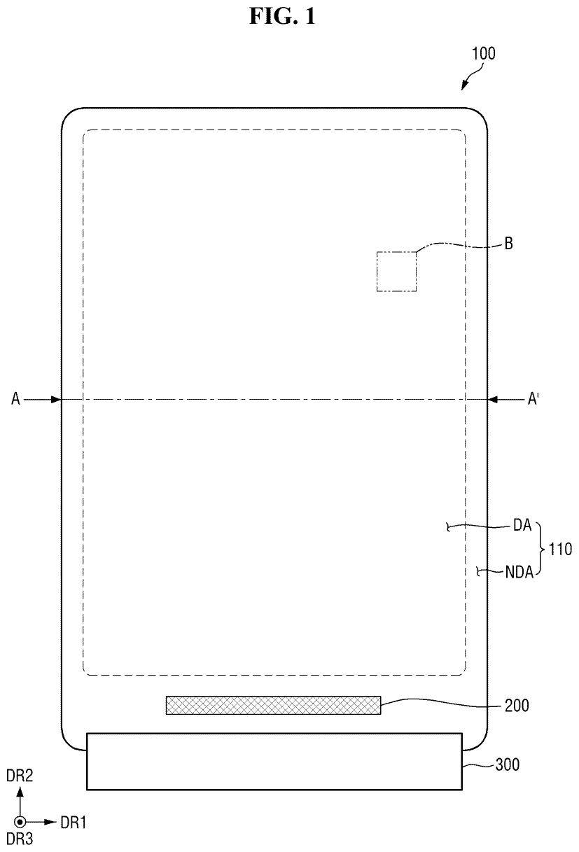

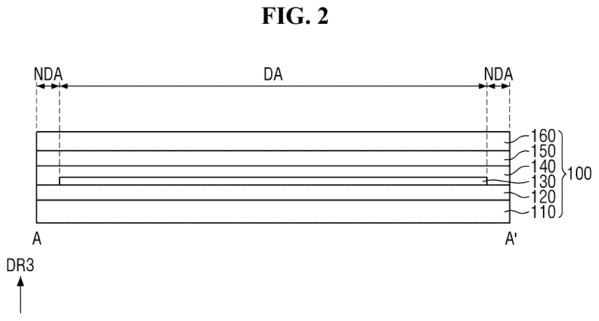

FIG. 1 is a plan view illustrating a display device according to embodiments. FIG. 2 is a cross-sectional view taken along line A-A′ of FIG. 1.

Referring to FIG. 1, a display device 100 is a device for displaying a moving image or a still image. The display device 100 may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, the present disclosure is not limited thereto, and may be applied to a display device including an organic insulating material, an organic light emitting material, and a metal material.

The display device 100 may be formed to be flat, but is not limited thereto. For example, the display device 100 may include a curved portion formed at left and right ends and having a constant curvature or a varying curvature. In addition, the display device 100 may be formed to be flexible so that it can be curved, bent, folded, or rolled.

The display device 100 includes a substrate 110.

The substrate 110 may include a display area DA disposed at most of the center of the display surface of the display device 100 and a non-display area NDA disposed around the display area DA.

The display area DA may, in plan view, be formed in a rectangular shape having short sides in a first direction DR1 and long sides in a second direction DR2 crossing the first direction DR1. The corner where the short side in the first direction DR1 and the long side in the second direction DR2 meet may be rounded to have a predetermined curvature or may be right-angled. The planar shape of the display area DA is not limited to the rectangular shape, and may be formed in another polygonal shape, a circular shape or an elliptical shape.

The non-display area NDA may be disposed at the edge of the substrate 110 to surround the display area DA.

For example, a part of the non-display area NDA may be deformed to be curved. In this case, another part connected to the curved part of the non-display area NDA may be disposed on the rear surface of the display device 100.

In accordance with embodiments, the display device 100 may further include a display driving circuit 200 mounted in the non-display area NDA of the substrate 110.

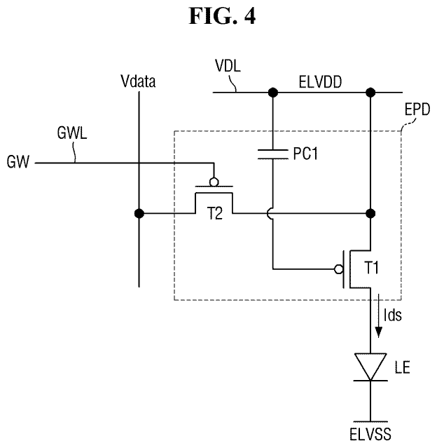

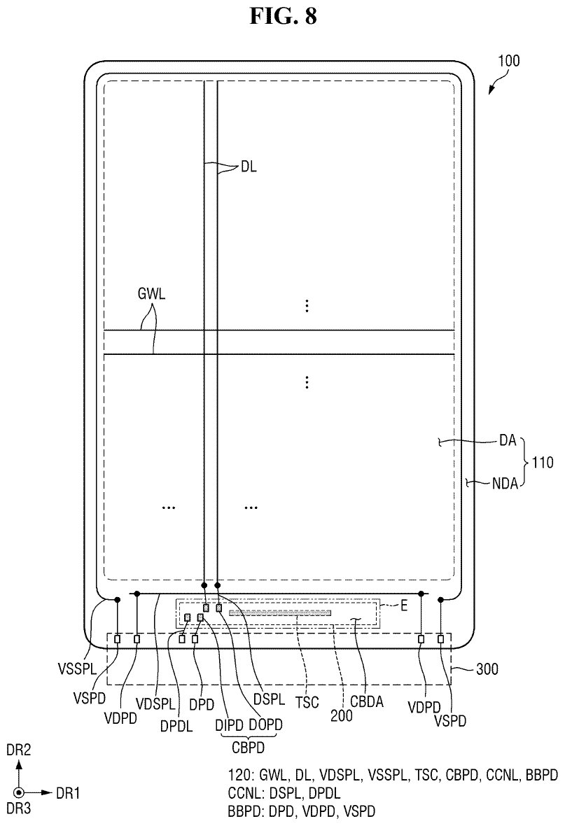

The display driving circuit 200 may supply a data signal Vdata (see FIG. 4) to data lines DL (see FIG. 8) of a circuit layer 120 (see FIG. 2).

In accordance with embodiments, the display device 100 may further include a circuit board 300 bonded to the edge of the substrate 110.

The circuit board 300 may supply signals and powers to the circuit layer 120 (see FIG. 2) and the display driving circuit 200.

Referring to FIG. 2, the display device 100 according to embodiments may include the substrate 110, the circuit layer 120 disposed on the substrate 110, the element layer 130 disposed on the circuit layer 120, an encapsulation layer 140 disposed on the element layer 130, and a touch sensor layer 150 disposed on the encapsulation layer 140.

Also, the display device 100 according to embodiments may further include a polarization layer 160 disposed on the touch sensor layer 150 to reduce reflection of external light.

The substrate 110 may be formed of an insulating material such as a polymer resin. For example, the substrate 110 may be formed of polyimide. The substrate 110 may be a flexible substrate which can be bent, folded or rolled.

Alternatively, the substrate 110 may be formed of an insulating material such as glass or the like.

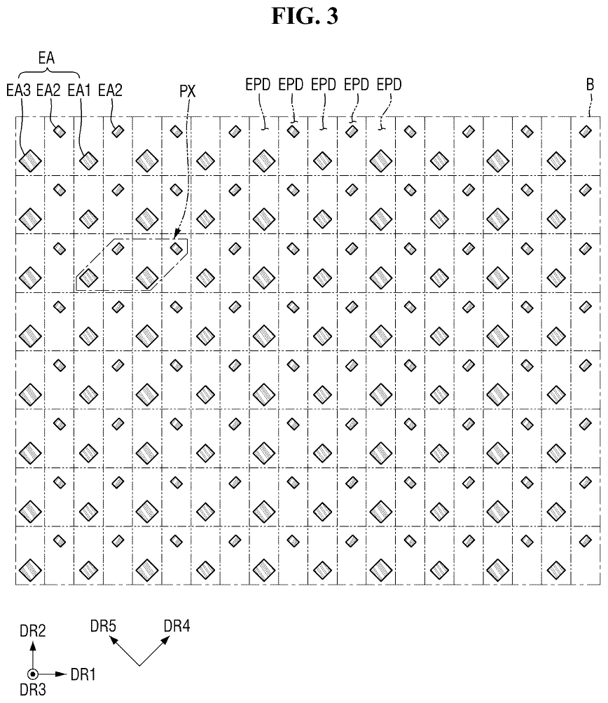

The substrate 110 may include the display area DA where emission areas EA (see FIG. 3) are arranged, and the non-display area NDA disposed around the display area DA.

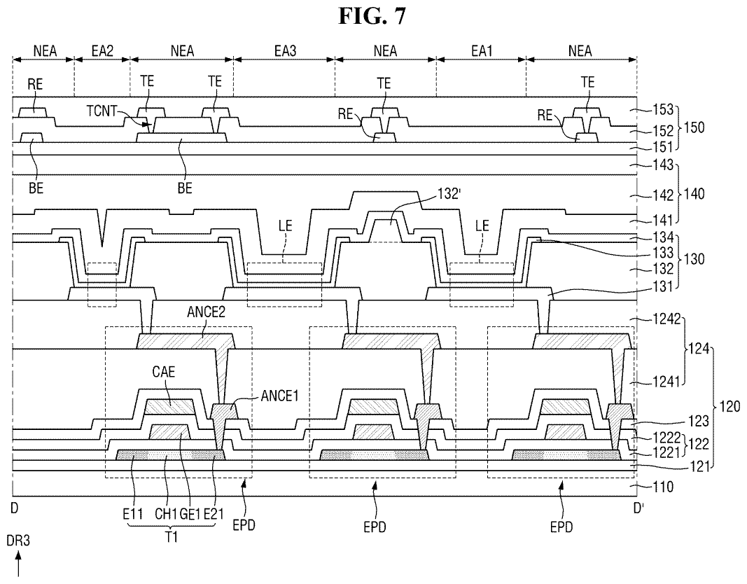

The circuit layer 120 may include a gate insulating layer 122 (see FIG. 7) disposed on the substrate 110, an interlayer-insulating layer 123 (see FIG. 7) disposed on the gate insulating layer 122 (see FIG. 7), and a planarization layer 124 (see FIG. 7) disposed on the interlayer-insulating layer 123 (see FIG. 7).

The element layer 130 may include light emitting elements LE (see FIGS. 4 and 7) disposed in the emission areas EA, respectively (see FIG. 3).

The encapsulation layer 140 may include a first encapsulation layer 141 (see FIG. 7) disposed on the element layer 130, a second encapsulation layer 142 (see FIG. 7) disposed on the first encapsulation layer 141 (see FIG. 7) and including a material different from that of the first encapsulation layer 141 (see FIG. 7), and a third encapsulation layer 143 (see FIG. 7) covering the second encapsulation layer 142 (see FIG. 7). Each of the first encapsulation layer 141 (see FIG. 7) and the third encapsulation layer 143 (see FIG. 7) may include an inorganic insulating material. The second encapsulation layer 142 (see FIG. 7) may include an organic insulating material.

The touch sensor layer 150 may include a touch buffer layer 151 (see FIG. 7) disposed on the encapsulation layer 140, and a touch interlayer-insulating layer 152 (see FIG. 7) disposed on the touch buffer layer 151 (see FIG. 7). The touch sensor layer 150 may further include a touch planarization layer 153 (see FIG. 7) disposed on the touch interlayer-insulating layer 152 (see FIG. 7).

FIG. 3 is a layout diagram illustrating part B of FIG. 1.

Referring to FIG. 3, the display area DA of the substrate 110 of the display device 100 according to embodiments may include the emission areas EA. In addition, the display area DA may further include a non-emission area disposed in a gap between the emission areas EA.

The element layer 130 may include the light emitting elements LE (see FIGS. 4 and 7) disposed in the emission areas EA, respectively.

The circuit layer 120 may include light emitting pixel drivers EPD electrically connected to the light emitting elements LE (see FIGS. 4 and 7) of the element layer 130, respectively.

The light emitting pixel drivers EPD may be arranged side by side in the first direction DR1 and the second direction DR2.

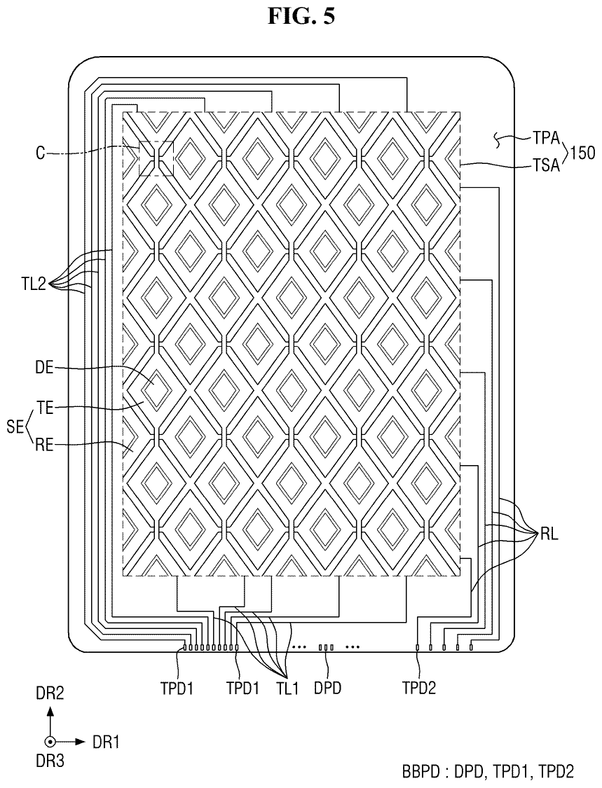

The emission areas EA may have a rhombus shape or a rectangular shape in plan view. However, this is only an example, and the planar shape of the emission areas EA according to one embodiment is not limited to the quadrilateral shape illustrated in FIG. 5.

That is, in plan view, each of the emission areas EA may have a polygonal shape such as a pentagon or hexagon, in addition to a quadrilateral shape, or may have a circular or elliptical shape including the edge of a curve.

The emission areas EA may include first emission areas EA1 for emitting light of a first color in a predetermined wavelength band, second emission areas EA2 for emitting light of a second color in a wavelength band lower than the wavelength band of the first color, and third emission areas EA3 for emitting light of a third color in a wavelength band lower than the wavelength band of the second color.

For example, the first color may be red having a wavelength band of approximately 600 (nm) to 750 nm. The second color may be green having a wavelength band of approximately 480 nm to 560 nm. The third color may be blue having a wavelength band of approximately 370 nm to 460 nm.

The first emission areas EA1 and the third emission areas EA3 may be alternately arranged in at least one of the first direction DR1 or the second direction DR2.

The second emission areas EA2 may be arranged side by side with each other in at least one of the first direction DR1 or the second direction DR2.

In addition, the second emission areas EA2 may be adjacent to the first emission areas EA1 and the third emission areas EA3 in diagonal directions DR4 and DR5 intersecting the first direction DR1 and the second direction DR2.

Pixels PX displaying their own luminances and colors may be provided by the first emission area EA1, the second emission area EA2, and the third emission area EA3 adjacent to each other among these emission areas EA.

In other words, the pixels PX may be a basic unit for displaying various colors including white with a predetermined luminance.

Each of the pixels PX may include at least one first emission area EA1, at least one second emission area EA2, and at least one third emission area EA3 that are adjacent to each other. Accordingly, each of the pixels PX may display various colors through a mixture of the light emitted from the first emission area EA1, the second emission area EA2, and the third emission area EA3 that are adjacent to each other.

FIG. 4 is an equivalent circuit diagram showing the light emitting pixel driver of FIG. 3.

Referring to FIG. 4, the light emitting pixel drivers EPD of the circuit layer 120 may be electrically connected to a first power ELVDD, and one the light emitting element LE of the light emitting elements LE of the element layer 130 may be electrically connected between one light emitting pixel driver EPD of the light emitting pixel drivers EPD of the circuit layer 120 and a second power ELVSS.

That is, the anode electrode of the light emitting element LE is electrically connected to the first power ELVDD through the light emitting pixel driver EPD, and the cathode electrode of the light emitting element LE may be electrically connected to the second power ELVSS having a voltage level lower than the first power ELVDD.

The circuit layer 120 may further include a first power line VDL for transmitting the first power ELVDD, a scan write line GWL for transmitting a scan write signal GW, and a data line DL for transmitting the data signal Vdata.

One light emitting pixel driver EPD of the circuit layer 120 may include a first transistor T1 for generating a driving current Ids for driving the light emitting element LE, a second transistor T2 electrically connected between the first transistor T1 and the data line DL, and a first pixel capacitor PC1 electrically connected between the first transistor T1 and the first power line VDL.

The first transistor T1 may be electrically connected between the first power ELVDD and the light emitting element LE.

That is, the first electrode (e.g., the source electrode) of the first transistor Tl may be electrically connected to the first power line VDL.

The second electrode (e.g., the drain electrode) of the first transistor T1 may be electrically connected to the anode electrode of the light emitting element LE.

The first electrode of the first transistor T1 may be electrically connected to the data line DL through a second transistor T2.

The second transistor T2 may be electrically connected between the data line DL and the first electrode of the first transistor T1.

The second transistor T2 may be turned on by the scan write signal GW of the scan write line GWL.

When the second transistor T2 is turned on in a state where the potential of the gate electrode of the first transistor T1 is maintained at a charging voltage of the first pixel capacitor PC1, the data signal Vdata of the data line DL may be transmitted to the first electrode of the first transistor T1.

Further, when the voltage difference between the gate electrode of the first transistor T1 and the first electrode becomes greater than a threshold voltage due to the difference voltage between the first power ELVDD and the data signal Vdata, the first transistor T1 may be turned on. In this case, the drain-source current Ids of the first transistor T1 may be generated to have a magnitude corresponding to the data signal Vdata.

Accordingly, the driving current Ids of the magnitude corresponding to the data signal Vdata may be supplied to the light emitting element LE through the first transistor T1, so that the light emitting element LE may emit light of luminance corresponding to the data signal Vdata.

As shown in FIG. 4, the first transistor T1 and the second transistor T2 may be provided as P-type MOSFETs. However, this is only an example, and at least one of the first transistor T1 or the second transistor T2 may be provided as an N-type MOSFET.

In addition, the light emitting pixel driver EPD according to embodiments is not limited to that illustrated in FIG. 4, and may further include one or more transistors and one or more pixel capacitors electrically connected to the first transistor T1 or the light emitting element LE in order to compensate or initialize each node.

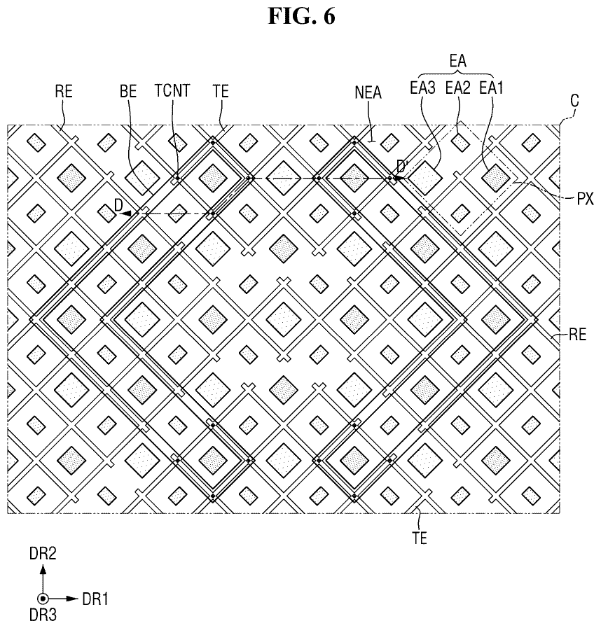

FIG. 5 is a plan view illustrating the touch sensor layer of FIG. 2 according to embodiments. FIG. 6 is an enlarged view showing part C of FIG. 5. FIG. 7 is a cross-sectional view taken along line D-D′ of FIG. 6.

FIG. 5 illustrates the touch sensor layer 150 of a capacitance method. In this case, the display device 100 may further include a touch driving circuit (not shown) that is mounted on the circuit board 300 (see FIG. 1) and senses a touch based on whether a capacitance changes or not. However, the illustration in FIG. 5 is only an example for easy description, and the touch sensor layer 150 according to embodiments is not limited to the illustration in FIG. 5.

FIG. 5 illustrates only some of the components of the touch sensor layer 150 for simplicity of description.

Referring to FIG. 5, the touch sensor layer 150 may include a touch sensing area TSA for sensing a user's touch and a touch peripheral area TPA around the touch sensing area TSA.

The touch sensing area TSA has a wider width than the display area DA or may be similar to the display area DA. Accordingly, the touch peripheral area TPA, which is a periphery of the touch sensing area TSA, may be similar to the non-display area NDA, which is a periphery of the display area DA.

For example, the touch sensing area TSA may overlap the display area DA and the edge of the non-display area NDA in contact with the display area DA. In this case, the touch peripheral area TPA may overlap the remaining part of the non-display area NDA that does not correspond to the touch sensing area TSA.

The touch sensor layer 150 may include sensor electrodes SE and dummy electrodes DE that are matrix-arranged in the touch sensing area TSA and generate mutual capacitance, and sensor lines TL1, TL2, and RE disposed in the touch peripheral area TPA.

The sensor electrodes SE may include a driving electrode TE (touch driving electrode) to which a driving signal is applied, and a sensing electrode RE (receiving electrode) to sense a voltage charged in mutual capacitance with the driving electrode TE.

The sensor lines TL1, TL2, and RL may be electrically connected to the touch pads TPD1 and TPD2 disposed in the touch peripheral area TPA and arranged on one side in the edge of the substrate 110.

The sensor lines TL1, TL2, and RL may include first driving lines TL1, second driving lines TL2, and sensing lines RL.

In accordance with embodiments, the circuit layer 120 (see FIG. 2) of the display device 100 may further include substrate bonding pads BBPD arranged on one side of the edge of the substrate 110 and connected to the circuit board 300 (see FIG. 1).

The substrate bonding pads BBPD may include the touch pads TPD1 and TPD2, and display pads DPD.

The touch pads TPD1 and TPD2 may include first touch pads TPD1 electrically connected to the first driving lines TL1 and the second driving lines TL2, and second touch pads TPD2 electrically connected to the sensing lines RL.

The display pads DPD may be electrically connected to the display driving circuit 200. For example, the display pads DPD may be arranged between the first touch pads TPD1 and the second touch pads TPD2 in the first direction DR1.

Each of the first driving lines TLI and the second driving lines TL2 may be electrically connected to two or more driving electrodes TE extending in the second direction DR2 among the driving electrodes TE.

The first driving lines TL1 may extend from one side of the touch sensing area TSA adjacent to the touch pads TPD1 and TPD2 to some of the first touch pads TDP1.

Ends of the first driving lines TL1 may be arranged in the first direction DR1 along one side of the touch sensing area TSA.

The second driving lines TL2 may extend from another side of the touch sensing area TSA facing one side where the first driving line TL1 is arranged to the remaining part of the first touch pads TDP1.

Ends of the second driving lines TL2 may be arranged in the first direction DR1 along another side of the touch sensing area TSA.

Each of the sensing lines RL may be electrically connected to two or more sensing electrodes RE extending in the first direction DR1 among the sensing electrodes RE.

The sensing lines RL may extend from still another side extending in the second direction DR2 to the second touch pads TPD2.

The sensing electrodes RE may be arranged side by side in the first direction DR1. The sensing electrodes RE adjacent in the first direction DR1 may be electrically connected to each other through a protruding portion in the first direction DR1.

The driving electrodes TE may be arranged side by side in the second direction DR2. The driving electrodes TE adjacent in the second direction DR2 may be electrically connected to each other through a bridge electrode BE (see FIGS. 6 and 7) in the second direction DR2.

Each of the driving electrodes TE and the sensing electrodes RE may have a shape surrounding the dummy electrode DE disposed in the center thereof.

Each of the dummy electrodes DE may be spaced apart from the driving electrode TE or the sensing electrode RE that surrounds it. The dummy electrode DE may be maintained in a floating state.

Although FIG. 5 illustrates that each of the driving electrode TE, the sensing electrode RE, and the dummy electrode DE has a rhombic planar shape, one embodiment is not limited to that illustrated in FIG. 5. For example, the planar shape of the driving electrode TE, the sensing electrode RE, and the dummy electrode DE may be a quadrilateral shape other than a rhombus, a polygonal shape other than a quadrilateral shape, a circular shape, or an elliptical shape.

Referring to FIG. 7, the driving electrode TE and the sensing electrode RE may be disposed on the touch interlayer-insulating layer 152 covering the bridge electrode BE.

As shown in FIGS. 5 and 6, the driving electrode TE and the sensing electrode RE may be spaced apart from each other.

As shown in FIG. 6, the bridge electrode BE may have a shape including at least one bent portion. However, this is only an example, and the shape of the bridge electrode BE according to one embodiment is not limited to that illustrated in FIG. 6.

The driving electrodes TE adjacent in the second direction DR2 may be electrically connected to each other through two or more bridge electrodes BE. In this way, reliability of the electrical connection between the driving electrodes TE may be improved.

Although FIG. 6 illustrates that two bridge electrodes BE parallel to each other are disposed between the driving electrodes TE adjacent to each other in the second direction DR2, one embodiment is not limited to that illustrated in FIG. 6.

The bridge electrode BE may be electrically connected to the driving electrodes TE through touch electrode connection holes TCNT.

The driving electrode TE, the sensing electrode RE, and the bridge electrode BE may have a mesh or net structure in plan view. The dummy electrodes DE may also have a mesh or net structure in plan view. In this way, since the overlapping width of the driving electrode TE, the sensing electrode RE, the dummy electrode DE, and the bridge electrode BE in the emission areas EA may be reduced, a decrease in light emission efficiency of the emission areas EA due to the driving electrode TE, the sensing electrode RE, the dummy electrode DE, and the bridge electrode BE may be reduced.

Referring to FIG. 7, the display device 100 according to embodiments may include the substrate 110, the circuit layer 120 on the substrate 110, the element layer 130 on the circuit layer 120, the encapsulation layer 140 on the element layer 130, and the touch sensor layer 150 on the encapsulation layer 140.

The circuit layer 120 may include the gate insulating layer 122 disposed on the substrate 110, the interlayer-insulating layer 123 disposed on the gate insulating layer 122, and the planarization layer 124 disposed on the interlayer-insulating layer 123.

The circuit layer 120 may further include the buffer layer 121 covering the substrate 110. In this case, the gate insulating layer 122 may be disposed on the buffer layer 121.

Each of the gate insulating layer 122 and the interlayer-insulating layer 123 may include an inorganic insulating material.

The planarization layer 124 may contain an organic insulating material.

The touch sensor layer 150 may include the touch buffer layer 151 disposed on the encapsulation layer 140, the touch interlayer-insulating layer 152 disposed on the touch buffer layer 151, and the touch planarization layer 153 disposed on the touch interlayer-insulating layer 152.

Each of the touch buffer layer 151 and the touch interlayer-insulating layer 152 may contain an inorganic insulating material.

The touch planarization layer 153 may contain an organic insulating material.

The element layer 130 may include the light emitting elements LE disposed in the emission areas EA, respectively.

According to embodiments, the circuit layer 120 may further include light emitting pixel drivers EPD electrically connected to the light emitting elements LE of the element layer 130, respectively.

As shown in FIG. 4, the light emitting pixel drivers EPD may include the first transistor T1, and one or more transistors T2 and one or more pixel capacitors PC1 electrically connected to the first transistor T1.

As shown in FIG. 7, in accordance with embodiments, the first transistor T1 may include a channel portion CH1, a first electrode portion E11, a second electrode portion E21, and a gate electrode GE1.

The channel portion CH1, the first electrode portion E11, and the second electrode portion E21 of the first transistor T1 may be disposed on the semiconductor layer on the buffer layer 121.

The first electrode portion E11 may be connected to one side of the channel portion CH1, and the second electrode portion E21 may be connected to the other side of the channel portion CH1.

The first electrode portion E11 of the first transistor T1 may be electrically connected to the first power line VDL (see FIG. 4).

The gate insulating layer 122 may include a first gate insulating layer 1221 covering the semiconductor layer CH1, E11, and E21, and a second gate insulating layer 1222 covering the first gate conductive layer G1 on the first gate insulating layer 1221.

The interlayer-insulating layer 123 may cover a second gate conductive layer CAE on the second gate insulating layer 1222.

The gate electrode GE1 may be disposed in the first gate conductive layer on the first gate insulating layer 1221.

The gate electrode GE1 may overlap the channel portion CH1.

Meanwhile, when the second transistor T2 (see FIG. 4) of each of the light emitting pixel drivers EPD is provided as a P-type MOSFET similarly to the first transistor T1, it has the same structure as that of the first transistor T1, so that the redundant description will be omitted.

Each light emitting pixel driver EPD of the circuit layer 120 may further include the capacitor electrode CAE disposed in the second gate conductive layer on the second gate insulating layer 1222 and overlapping the gate electrode GE1 of the first transistor T1.

The first pixel capacitor PC1 (see FIG. 4) may be provided by the overlapping area between the gate electrode GE1 of the first transistor T1 and the capacitor electrode CAE.

The planarization layer 124 may include a first planarization layer 1241 covering a first source-drain conductive layer ANCE1 on the interlayer-insulating layer 123, and a second planarization layer 1242 covering a second source-drain conductive layer ANCE2 on the first planarization layer 1241.

Each light emitting pixel driver EPD of the circuit layer 120 may further include a first anode connection electrode ANCE1 disposed in the first source-drain conductive layer on the interlayer-insulating layer 123, and a second anode connection electrode ANCE2 disposed in the second source-drain conductive layer on the first planarization layer 1241.

The first anode connection electrode ANCE1 may be electrically connected to the second electrode portion E21 of the first transistor T1 through a connection hole penetrating the interlayer-insulating layer 123, the second gate insulating layer 1222, and the first gate insulating layer 1221.

The second anode connection electrode ANCE2 may be electrically connected to the first anode connection electrode ANCE1 through a connection hole penetrating the first planarization layer 1241.

Each of the buffer layer 121, the first gate insulating layer 1221, the second gate insulating layer 1222, and the interlayer-insulating layer 123 may be formed of at least one inorganic layer. For example, each of the buffer layer 121, the first gate insulating layer 1221, the second gate insulating layer 1222, and the interlayer-insulating layer 123 may include one or more inorganic layers of a silicon nitride layer, a silicon oxynitride layer, a silicon oxide layer, a titanium oxide layer, and an aluminum oxide layer.

Each of the first planarization layer 1241 and the second planarization layer 1242 may include an organic layer such as acryl resin, epoxy resin, phenolic resin, polyamide resin, polyimide resin and the like.

The semiconductor layer CH1, E11, and E21 may include one semiconductor material among poly silicon, amorphous silicon, and an oxide semiconductor.

Each of the first gate conductive layer G1, the second gate conductive layer CAE, the first source-drain conductive layer ANCE1, and the second source-drain conductive layer ANCE2 may be formed as a multilayer of two or more of molybdenum (Mo), aluminum (Al), chromium (Cr), gold (Au), titanium (Ti), nickel (Ni), neodymium (Nd), and copper (Cu).

Each of the first source-drain conductive layer ANCE1 and the second source-drain conductive layer ANCE2 may include a multi-layer structure in which two or more metal layers are stacked.

The element layer 130 may be disposed on the planarization layer 124, and may include the light emitting elements LE disposed in the emission areas EA, respectively.

The element layer 130 may include anode electrodes 131 disposed in the emission areas EA, respectively, a pixel defining layer 132 disposed in the non-emission area NEA that is a separation region between the emission areas EA and covering the edge of each of the anode electrodes 131, a spacer layer 132′ disposed on a part of the pixel defining layer 132, light emitting layers 133 disposed on the anode electrodes 131, respectively, and a cathode electrode 134 disposed on the pixel defining layer 132, the spacer layer 132′, and the light emitting layers 133.

That is, each of the light emitting elements LE may include the anode electrode 131 and the cathode electrode 134 facing each other, and the light emitting layer 133 disposed therebetween.

The element layer 130 may further include first common layers disposed between the anode electrodes 131 and the light emitting layers 133, and a second common layer disposed between the light emitting layers 133 and the cathode electrode 134.

The anode electrode 131 may be disposed on the second planarization layer 1242, and may be electrically connected to the second anode connection electrode ANCE2 through a connection hole penetrating the second planarization layer 1242.

Accordingly, the anode electrode 131 may be electrically connected to the second electrode portion E21 of the first transistor T1 through the second anode connection electrode ANCE2 and the first anode connection electrode ANCE1.

The first common layer on the anode electrode 131 may include a hole transport layer. Alternatively, the first common layer may further include a hole injection layer between the anode electrode 131 and the hole transport layer.

The light emitting layer 133 may be disposed on the first common layer.

The light emitting layer 133 of the first emission area EA1, the light emitting layer 133 of the second emission area EA2, and the light emitting layer 133 of the third emission area EA3 may include organic light emitting materials having different materials or contents.

For example, the light emitting layer 133 may be formed of an organic light emitting material that converts electron-hole pairs into light. The organic light emitting material may include a host material and a dopant. The dopant may include a phosphorescent material or a fluorescent material.

The cathode electrode 134 and the second common layer disposed below the cathode electrode 134 may be entirely disposed in the display area DA including the emission areas EA and the non-emission area NEA.

The second common layer may include an electron transport layer. Alternatively, the second common layer may further include an electron injection layer between the cathode electrode 134 and the electron transport layer.

The encapsulation layer 140 may be disposed on the circuit layer 120 and cover the element layer 130.

The encapsulation layer 140 may include a first encapsulation layer 141 disposed on the element layer 130, a second encapsulation layer 142 disposed on the first encapsulation layer 141 and overlapping the element layer 130, and a third encapsulation layer 143 disposed on the first encapsulation layer 141 and covering the second encapsulation layer 142.

Each of the first encapsulation layer 141 and the third encapsulation layer 143 may have a structure in which one or more inorganic layers of a silicon nitride layer, a silicon oxynitride layer, a silicon oxide layer, a titanium oxide layer, and an aluminum oxide layer are stacked.

The second encapsulation layer 142 may include an organic insulating material such as acryl resin, epoxy resin, phenolic resin, polyamide resin, polyimide resin and the like.

In accordance with embodiments, the bridge electrode BE of the touch sensor layer 150 may be disposed in the first touch conductive layer on the touch buffer layer 151, and the driving electrode TE and the sensing electrode RE may be disposed in the second touch conductive layer on the touch interlayer-insulating layer 152.

The dummy electrode DE disposed inside each of the driving electrode TE and the sensing electrode RE, the first driving line TL1 and the second driving line TL2 connected to the driving electrode TE, and the sensing line RL connected to the sensing electrode RE may be disposed in the second touch conductive layer on the touch interlayer-insulating layer 152, similarly to the driving electrode TE and the sensing electrode RE.

The driving electrode TE may be electrically connected to the bridge electrode BE through the touch electrode connection hole TCNT penetrating the touch interlayer-insulating layer 152.

The touch planarization layer 153 may cover the second touch conductive layer TE and RE on the touch interlayer-insulating layer 152.

Each of the touch buffer layer 151 and the touch interlayer-insulating layer 152 may have a structure in which one or more inorganic layers of a silicon nitride layer, a silicon oxynitride layer, a silicon oxide layer, a titanium oxide layer, and an aluminum oxide layer are stacked.

The touch planarization layer 153 may include an organic insulating material such as acryl resin, epoxy resin, phenolic resin, polyamide resin, polyimide resin and the like.

FIG. 8 is a plan view showing the substrate and the circuit layer of FIG. 2 according to embodiments.

Referring to FIG. 8, the display device 100 according to embodiments may include the substrate 110, the circuit layer 120, the display driving circuit 200, and the circuit board

The substrate 110 may include the display area DA disposed at the center of one surface and in which the emission areas EA (see FIG. 3) are arranged, and the non-display area NDA disposed around the display area DA.

The circuit layer 120 may be disposed on the substrate 110.

The circuit layer 120 may include the scan write lines GWL disposed in the display area DA and extending in the first direction DR1, and the data lines DL disposed in the display area DA and extending in the second direction DR2.

The circuit layer 120 may further include a first power supply line VDSPL that is disposed in the non-display area NDA and transmits the first power ELVDD (see FIG. 4), and a second power supply line VSSPL that is disposed in the non-display area NDA and transmits the second power ELVSS (see FIG. 4).

The circuit layer 120 may further include circuit bonding pads CBPD disposed in a circuit bonding area CBDA on which the display driving circuit 200 is mounted in the non-display area NDA, circuit connection lines CCNL electrically connected to the circuit bonding pads CBPD, respectively, and the substrate bonding pads BBPD arranged side by side with one side adjacent to the circuit bonding pads CBPD in the edge of the substrate 110 and connected to the circuit board 300.

When the display driving circuit 200 is mounted, the edge of the circuit bonding area CBDA is arranged side by side with the edge of the display driving circuit 200, so that reference numerals related to the edge of the circuit bonding area CBDA may also be used for description related to the edge of the display driving circuit 200 in the following description and drawings.

The circuit bonding pads CBPD may include data output pads DOPD electrically connected to the output terminals of the display driving circuit 200, and data input pads DIPD electrically connected to the input terminals of the display driving circuit 200.

The circuit connection lines CCNL may include data supply lines DSPL electrically connected to the data output pads DOPD and extending to the edge of the display area DA, and data pad lines DPDL electrically connected to the data input pads DIPD and extending to the display pads DPD that are some of the substrate bonding pads BBPD.

The substrate bonding pads BBPD may include the display pads DPD electrically connected to the display driving circuit 200 through the data pad lines DPDL and the data input pads DIPD, one or more first power supply pads VDPD electrically connected to the first power supply line VDSPL, and one or more second power supply pads VSPD electrically connected to the second power supply line VSSPL.

Further, as shown in FIG. 5, the substrate bonding pads BBPD may further include the touch pads TPD1 and TPD2.

As shown in FIG. 8, in accordance with embodiments, the display driving circuit 200 are bonded to the circuit bonding pads CBPD disposed in the circuit bonding area CBDA, and thus may be mounted in the circuit bonding area CBDA.

Further, the circuit board 300 is bonded to the board bonding pads BBPD, and thus may be electrically connected to the display driving circuit 200 and the circuit layer 120 and fixed to one side of the substrate 110.

In accordance with embodiments, the circuit layer 120 of the display device 100 may further include a lighting circuit TSC disposed in a part of the circuit bonding area CBDA.

The lighting circuit TSC may supply various test signals for verifying whether or not the light emitting elements LE (see FIG. 7) of the element layer 130 are normally driven in response to an external input before the display driving circuit 200 and the circuit board 300 are bonded.

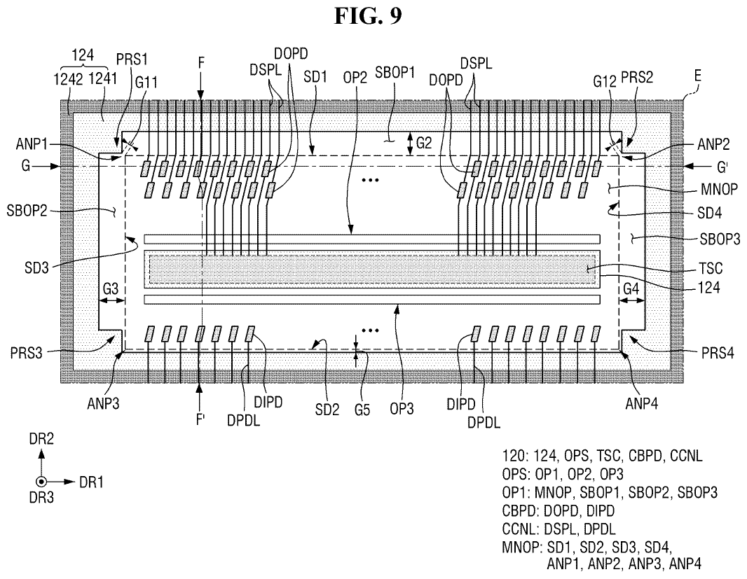

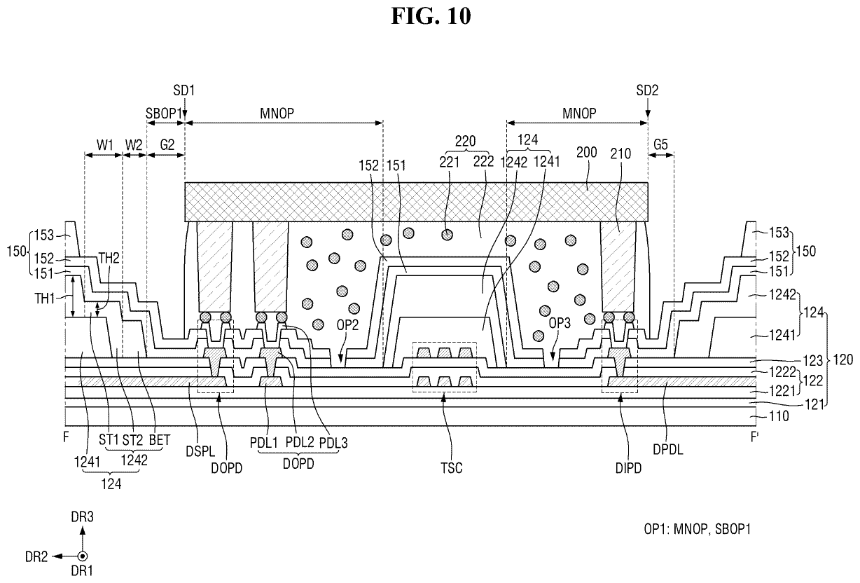

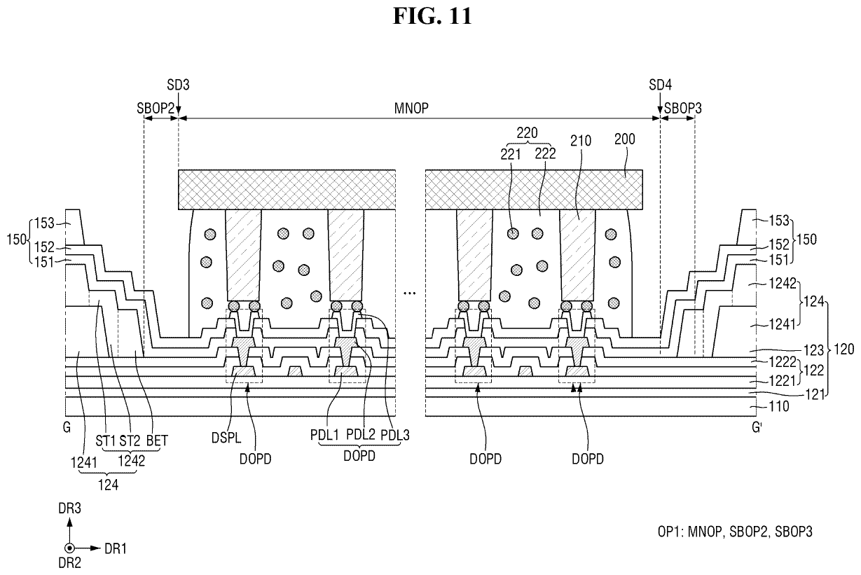

FIG. 9 is a plan view showing part E of FIG. 8 according to one embodiment. FIG. 10 is a cross-sectional view taken along line F-F′ of FIG. 9. FIG. 11 is a cross-sectional view taken along line G-G′ of FIG. 9.

As shown in FIG. 9, the circuit layer 120 of the display device 100 according to embodiments may include a first opening OP1 overlapping the display driving circuit 200 (see FIG. 8) and penetrating the planarization layer 124.

In accordance with embodiments, the first opening OP1 may include a main opening MNOP overlapping the display driving circuit 200 (see FIG. 8), and a first sub-opening SBOP1 extending from a first side SD1 facing the display area DA (see FIG. 8) in the edge of the main opening MNOP and disposed between the main opening MNOP and the display area DA (see FIG. 8).

The edge of the main opening MNOP may further include, in addition to the first side SD1, a second side SD2 facing the first side SD1, and a third side SD3 and a fourth side SD4 connected between the first side SD1 and the second side SD2 and facing each other. The first side SD1 and the second side SD2 may extend in the first direction DR1, and the third side SD3 and the fourth side SD4 may extend in the second direction DR2.

Accordingly, the edge of the main opening MNOP may further include a first vertex ANP1 between the first side SD1 and the third side SD3, a second vertex ANP2 between the first side SD1 and the fourth side SD4, a third vertex ANP3 between the second side SD2 and the third side SD3, and a fourth vertex ANP4 between the second side SD2 and the fourth side SD4.

In accordance with embodiments, the first opening OP1 includes the first sub-opening SBOP1 extending from the first side SD1 of the main opening MNOP.

Accordingly, in the second direction DR2 in which the first side SD1 and the second side SD2 face each other, a gap G2 (i.e., minimum gap in the second direction DR2) between the first side SD1 and the planarization layer 124 may be greater than a gap G5 (see FIG. 10) between the second side SD2 and the planarization layer 124 due to the width of the first sub-opening SBOP1.

In other words, the first opening OP1 penetrating the planarization layer 124 includes the first sub-opening SBOP1 as well as the main opening MNOP overlapping the display driving circuit 200 (see FIG. 8), and thus may extend to be wider than the display driving circuit 200 (see FIG. 8) toward the display area DA (i.e., in the second direction DR2) (see FIG. 8).

In this way, the planarization layer 124 may be spaced apart from the display driving circuit 200 (see FIG. 8) by the width of the first sub-opening SBOP1 between the display driving circuit 200 (see FIG. 8) and the display area DA, so that deformation of the organic insulating material of the planarization layer 124 due to high-temperature and high-pressure stress during the mounting process of the display driving circuit 200 (see FIG. 8) may be reduced. Therefore, disconnection defects or short-circuit defects of the data supply lines DSPL that electrically connect the display driving circuit 200 (see FIG. 8) and the data lines DL (see FIG. 8) of the display area DA may be reduced.

For example, in the second direction DR2, the width (i.e., the gap G2) of the first sub-opening SBOP1 may be within a range from approximately 50 micrometers (μm) to 100 μm.

When the width (i.e., the gap G2) of the first sub-opening SBOP1 exceeds approximately 100 μm, the inorganic insulating layers 121, 122, and 123 (see FIG. 10) of the circuit layer 120 that are not covered with the planarization layer 124 due to the first sub-opening SBOP1 may become susceptible to lifting defects or crack defects.

On the other hand, when the width (i.e., the gap G2) of the first sub-opening SBOP1 is less than approximately 50 μm, the deformation of the organic insulating material of the planarization layer 124 due to high-temperature and high-pressure stress during the mounting process of the display driving circuit 200 (see FIG. 8) may not be reduced.

In accordance with embodiments, the planarization layer 124 may include a first protrusion PRS1 adjacent to the first vertex ANP1 between the first side SD1 and the third side SD3 of the main opening MNOP, and a second protrusion PRS2 adjacent to the second vertex ANP2 between the first side SD1 and the fourth side SD4 of the main opening MNOP.

That is, the first sub-opening SBOP1 may be in contact with the first protrusion PRS1 and the second protrusion PRS2 of the planarization layer 124 in the first direction DR1.

In this way, since the planarization layer 124 includes the first protrusion PRS1 and the second protrusion PRS2, a minimum gap G11 between the first vertex ANP1 and the planarization layer 124 and a minimum gap G12 between the second vertex ANP2 and the planarization layer 124 may each become smaller than the minimum gap G2 between the first side SD1 and the planarization layer 124 in the second direction DR2.

That is, even if the first opening OP1 includes the first sub-opening SBOP1, the inorganic insulating layers 121, 122, and 123 (see FIG. 10) of the circuit layer 120 may be protected by the first protrusion PRS1 and the second protrusion PRS2 at both ends of the first sub-opening SBOP1 in the first direction DR1. Therefore, at the bent corners (i.e., corresponding to the first vertex ANP1 and the second vertex ANP2) adjacent to the display area DA in the edge of the display driving circuit 200 (see FIG. 8), lifting defects or crack defects of the inorganic insulating layers 121, 122, and 123 (see FIG. 10) of the circuit layer 120 may be reduced.

Accordingly, the lifespan of the display device 100 may be improved.

In accordance with one embodiment, as shown in FIG. 9, the planarization layer 124 may further include a third protrusion PRS3 adjacent to the third vertex ANP3 between the second side SD2 and the third side SD3 of the main opening MNOP, and a fourth protrusion PRS4 adjacent to the fourth vertex ANP4 between the second side SD2 and the fourth side SD4 of the main opening MNOP.

In accordance with one embodiment, the third protrusion PRS3 may be disposed adjacent to a part of the third side SD3. That is, the third protrusion PRS3 may be disposed side by side with a part of the third side SD3.

Further, the fourth protrusion PRS4 may be disposed adjacent to a part of the fourth side SD4. That is, the fourth protrusion PRS4 may be disposed side by side with a part of the fourth side SD4.

In accordance with one embodiment, the first opening OP1 may further include a second sub-opening SBOP2 extending from another part of the third side SD3 except a part adjacent to the third protrusion PRS3, and a third sub-opening SBOP3 extending from another part of the fourth side SD4 except a part adjacent to the fourth protrusion PRS4.

Accordingly, a gap G3 between the third side SD3 and the planarization layer 124 in the first direction DR1 in which the third side SD3 and the fourth side SD4 face each other may become greater than a gap G5 (see FIG. 10) between the second side SD2 and the planarization layer 124 in the second direction DR2 due to the width (i.e., gap G3) of the second sub-opening SBOP2.

Further, a gap G4 between the fourth side SD4 and the planarization layer 124 in the first direction DR1 in which the third side SD3 and the fourth side SD4 face each other may become greater than the gap G5 (see FIG. 10) between the second side SD2 and the planarization layer 124 in the second direction DR2 due to the width (i.e., gap G4) of the third sub-opening SBOP3.

That is, the first opening OP1 penetrating the planarization layer 124 includes not only the main opening MNOP overlapping the display driving circuit 200 (see FIG. 8) but also the first sub-opening SBOP1, the second sub-opening SBOP2, and the third sub-opening SBOP3, and thus may extend to be wider than the display driving circuit 200 (see FIG. 8) in a direction toward the display area DA (see FIG. 8) (i.e., in the second direction DR2).

In this way, the planarization layer 124 may be spaced apart from the display driving circuit 200 (see FIG. 8) by the width of the first sub-opening SBOP1 between the display driving circuit 200 (see FIG. 8) and the display area DA, so that deformation of the organic insulating material of the planarization layer 124 due to high-temperature and high-pressure stress during the mounting process of the display driving circuit 200 (see FIG. 8) may be reduced. Therefore, lifting defects or crack defects of the touch interlayer-insulating layer 152 and the touch buffer layer 151 disposed on the planarization layer 124 may be reduced.

The second sub-opening SBOP2 may be in contact with the first protrusion PRS1 and the third protrusion PRS3 in the second direction DR2.

The third sub-opening SBOP3 may be in contact with the second protrusion PRS2 and the fourth protrusion PRS4 in the second direction DR2.

That is, in accordance with one embodiment, the planarization layer 124 includes the first protrusion PRS1, the second protrusion PRS2, the third protrusion PRS3, and the fourth protrusion PRS4, so that the minimum gap between the planarization layer 124 and each of the vertices ANP1, ANP2, ANP3, and ANP4 where two sides extending in different directions in the edge of the main opening MNOP are connected may become smaller than the minimum gap G2 between the planarization layer 124 and the first side SD1 of the main opening MNOP in the second direction DR2.

In this way, lifting defects or crack defects of the inorganic insulating layers 121, 122, and 123 (see FIG. 10) of the circuit layer 120 may be effectively reduced at the bent corners in the edge of the display driving circuit 200. Accordingly, the lifespan of the display device 100 may be further improved.

As shown in FIG. 9, the circuit layer 120 of the display device 100 according to embodiments may include the circuit bonding pads CBPD arranged in the main opening MNOP of the first opening OP1 and to which the display driving circuit 200 (see FIG. 8) is bonded, the circuit connection lines CCNL electrically connected to the circuit bonding pads CBPD, respectively, and the substrate bonding pads BBPD (see FIG. 8) connected to the circuit board 300 (see FIG. 1).

The circuit bonding pads CBPD may include the data output pads DOPD disposed adjacent to the first side SD1 of the main opening MNOP that faces the display area DA, and the data input pads DIPD disposed adjacent to the second side SD2 of the main opening MNOP that faces the first side SD1.

For example, the data output pads DOPD may be arranged in two or more pad columns adjacent in the second direction DR2.

Each of two or more pad columns may include the data output pads DOPD arranged side by side in the first direction DR1.

The data output pads DOPD arranged in adjacent pad columns may not be arranged side by side in the second direction DR2, and may be adjacent in a diagonal direction. In this way, the disposition of the data supply lines DSPL connected to the data output pads DOPD, respectively, may become easier.

The circuit connection lines CCNL may include the data supply lines DSPL electrically connected to the data output pads DOPD, respectively, and the data pad lines DPDL electrically connected to the data input pads DIPD, respectively.

In accordance with embodiments, the circuit layer 120 may further include the lighting circuit TSC disposed between the data output pads DOPD and the data input pads DIPD.

The lighting circuit TSC is surrounded by the main opening MNOP of the first opening OP1, and thus may overlap the display driving circuit 200 and may be covered with the planarization layer 124. Accordingly, even if the lighting circuit TSC overlaps the display driving circuit 200, it may be electrically and physically protected by the planarization layer 124.

As shown in FIG. 10, in accordance with embodiments, the planarization layer 124 of the organic insulating material in the circuit layer 120 may include a first planarization layer 1241 disposed on the interlayer-insulating layer 123, and a second planarization layer 1242 covering the first planarization layer 1241.

The second planarization layer 1242 may include a first step portion ST1 disposed with a first thickness TH1 on the first planarization layer 1241, a bottom extension portion BET facing the first opening OP1 and in contact with the interlayer-insulating layer 123, and a second step portion ST2 disposed between the first step portion ST1 and the bottom extension portion BET.

A part of the second step portion ST2 that is adjacent to the first step portion ST1 may be disposed with a second thickness TH2 smaller than the first thickness TH1 on the first planarization layer 1241.

In accordance with embodiments, in the second direction DR2 in which the first side SD1 and the second side SD2 face each other, a part of the second step portion ST2 of the second planarization layer 1242 that faces the first side SD1 may be disposed with a width W1 greater than the gap G2 between the first side SD1 and the planarization layer 124.

Further, in the second direction DR2 in which the first side SD1 and the second side SD2 face each other, a part of the bottom extension portion BET of the second planarization layer 1242 that faces the first side SD1 of the second planarization layer 1242 may be disposed with a width W2 smaller than the gap G2 between the first side SD1 and the planarization layer 124.

In this way, since the second planarization layer 1242 includes the second step portion ST2 with the second thickness TH2 that is relatively small, the amount of the organic insulating material disposed around the display driving circuit 200 (see FIG. 8) is reduced, thereby reducing the influence of high-temperature and high-pressure stress during the mounting process of the display driving circuit 200 (see FIG. 8) on the planarization layer 124 of the organic insulating material. Therefore, lifting defects or crack defects of the inorganic insulating layers disposed on the planarization layer 124, that is, the touch interlayer-insulating layer 152 and the touch buffer layer 151, may be reduced.

As shown in FIG. 9, in accordance with embodiments, the circuit layer 120 may further define, in the second direction DR2 in which the first side SD1 and the second side SD2 face each other, a second opening OP2 located between the data output pads DOPD and the lighting circuit TSC, and a third opening OP3 located between the data input pads DIPD and the lighting circuit TSC.

The second opening OP2 may extend side by side with the first side SD1.

The third opening OP3 may extend side by side with the second side SD2.

As shown in FIG. 10, each of the second opening OP2 and the third opening OP3 may penetrate at least the touch interlayer-insulating layer 152 among the touch buffer layer 151 and the touch interlayer-insulating layer 152. For example, each of the second opening OP2 and the third opening OP3 may penetrate the touch buffer layer 151 and the touch interlayer-insulating layer 152.

Due to the second opening OP2, during the mounting process of the display driving circuit 200, cracks generated at the touch buffer layer 151 and the touch interlayer-insulating layer 152 on the planarization layer 124 covering the lighting circuit TSC may be effectively prevented from spreading to the data output pads DOPD and the data supply lines DSPL.

Similarly, due to the third opening OP3, during the mounting process of the display driving circuit 200, cracks generated at the touch buffer layer 151 and the touch interlayer-insulating layer 152 on the planarization layer 124 covering the lighting circuit TSC may be effectively prevented from spreading to the data input pads DIPD and the data pad lines DPDL.

As shown in FIGS. 10 and 11, each of the circuit bonding pads CBPD (see FIG. 9) and DOPD and DIPD (see FIG. 10) may include a first pad layer PDL1, a second pad layer PDL2, and a third pad layer PDL3.

The first pad layer PDL1 may be disposed in the first gate conductive layer on the first gate insulating layer 1221 or in the second gate conductive layer on the second gate insulating layer 1222.

The second pad layer PDL2 may be disposed in the first source-drain conductive layer on the interlayer-insulating layer 123, and may be electrically connected to the first pad layer PDL1 through a connection hole penetrating the gate insulating layer 122 and the interlayer-insulating layer 123.

The third pad layer PDL3 may be disposed in the second touch conductive layer on the touch interlayer-insulating layer 152, and may be electrically connected to the second pad layer PDL2 through a connection hole penetrating the touch buffer layer 151 and the touch interlayer-insulating layer 152.

As shown in FIG. 10, each of the circuit connection lines CCNL (see FIG. 9) and DSPL and DPDL (see FIG. 10) may be disposed in the first gate conductive layer on the first gate insulating layer 1221 or in the second gate conductive layer on the second gate insulating layer 1222. For example, each of the circuit connection lines CCNL (see FIG. 9) and DSPL and DPDL (see FIG. 10) may be connected to the first pad layer PDL1 of each of the circuit bonding pads CBPD (see FIG. 9) and DOPD and DIPD (see FIG. 10).

The lighting circuit TSC may include wires or electrodes disposed in the first gate conductive layer on the first gate insulating layer 1221 or in the second gate conductive layer on the second gate insulating layer 1222.

The display driving circuit 200 may be mounted in the non-display area NDA of the substrate 110 by a conductive adhesive member 220.

For example, the display driving circuit 200 may include bumps 210 facing the circuit bonding pads CBPD (see FIG. 9) and DOPD and DIPD (see FIGS. 10 and 11).

The conductive adhesive member 220 may include a resin member 222 in which conductive balls 221 are dispersed and having an adhesive property.

Since the conductive balls 221 of the conductive adhesive member 220 are interposed between the bumps 210 and the circuit bonding pads CBPD (see FIG. 9) and DOPD and DIPD (see FIGS. 10 and 11), the bumps 210 of the display driving circuit 200 may be electrically connected to the circuit bonding pads CBPD (DOPD and DIPD of FIG. 9).

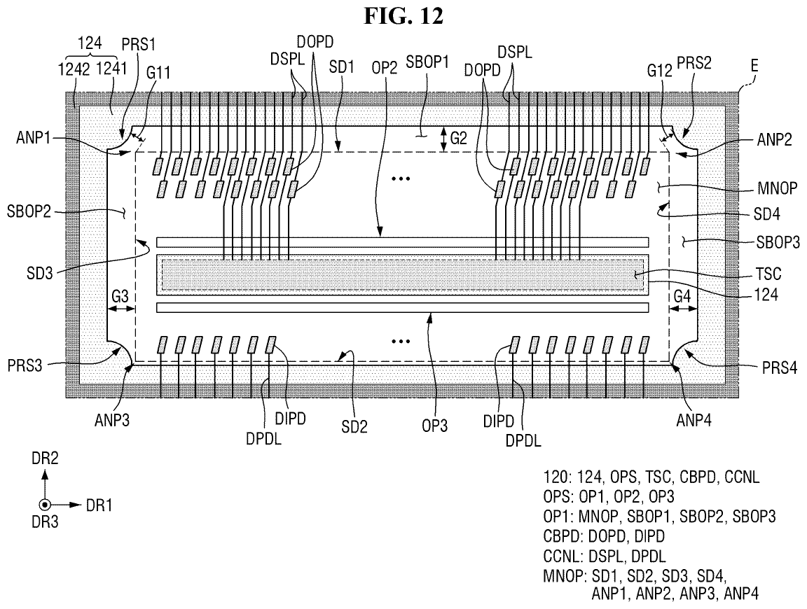

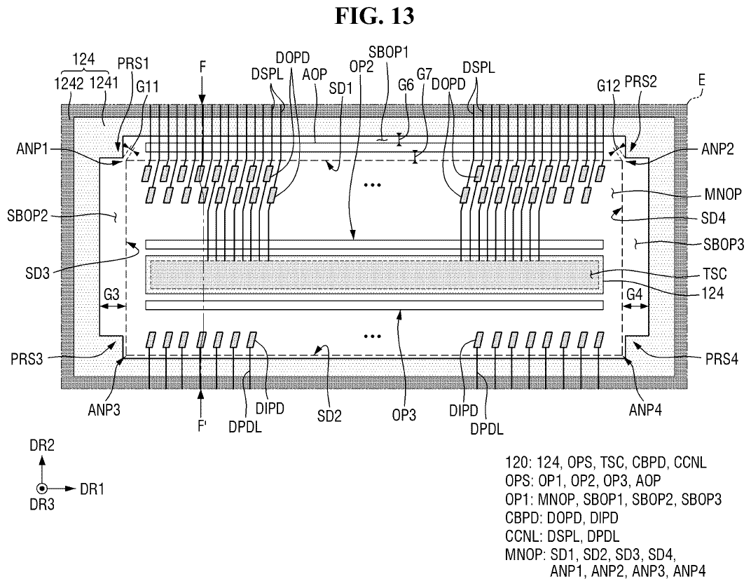

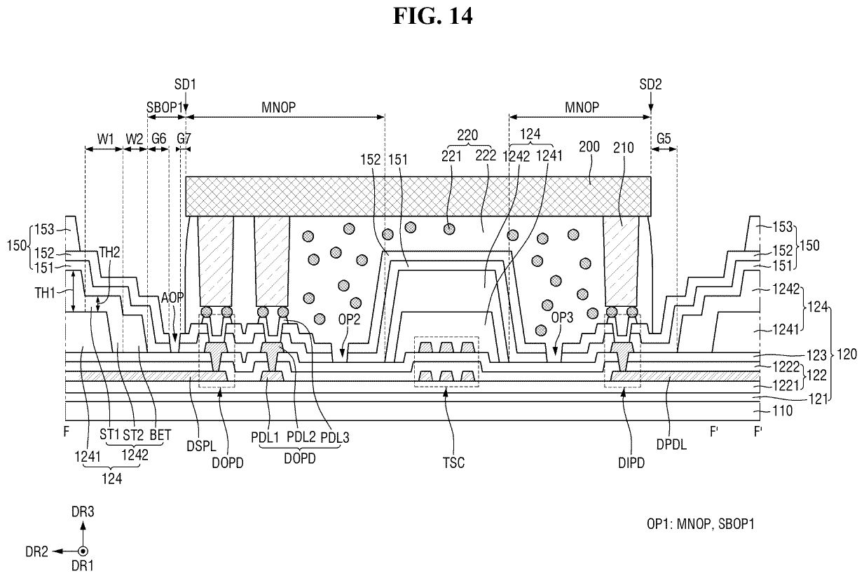

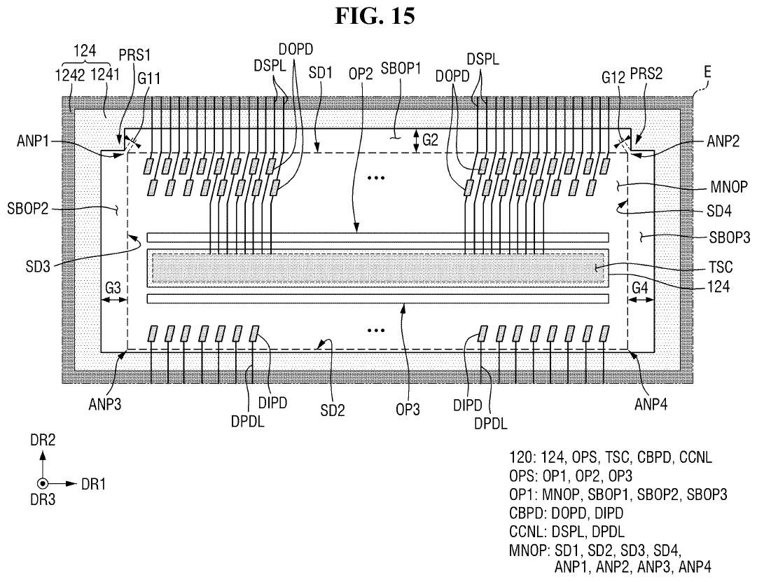

FIGS. 12 and 13 are plan views showing part E of FIG. 8 according to embodiments. FIG. 14 is a cross-sectional view taken along line F-F′ of FIG. 13. FIG. 15 is a plan view showing part E of FIG. 8 according to one embodiment.

The display device 100 of one embodiment shown in FIG. 12 is substantially the same as the embodiments shown in FIGS. 9 to 11 except that one side facing the main opening MNOP has an arc shape at each of the first protrusion PRS1, the second protrusion PRS2, the third protrusion PRS3, and the fourth protrusion PRS4 of the planarization layer 124 of the circuit layer 120, so that the redundant description will be omitted below.

In this way, the bent corners in the edge of the display driving circuit 200 are protected by the planarization layer 124, so that lifting defects or crack defects of the inorganic insulating layers 121, 122, and 123 (see FIG. 10) of the circuit layer 120 may be reduced, and the area of each of the first sub-opening SBOP1, the second sub-opening SBOP2, and the third sub-opening SBOP3 of the first opening OP1 may be increased.

Accordingly, the deformation of the organic insulating material due to high-temperature and high-pressure stress during the mounting process of the display driving circuit 200 (see FIG. 8) may be reduced, thereby reducing disconnection defects or short-circuit defects of the data supply lines DSPL and reducing lifting defects or crack defects of the touch interlayer-insulating layer 152 and the touch buffer layer 151.

The display device 100 of one embodiment shown in FIGS. 13 and 14 is substantially the same as the embodiments shown in FIGS. 9 to 12 except that the circuit layer 120 further defines an auxiliary opening AOP, so that the redundant description will be omitted below.

The auxiliary opening AOP may be located inside the first sub-opening SBOP1 and may extend side by side with the first side SD1.

Similarly to the second opening OP2, the auxiliary opening AOP may penetrate at least the touch interlayer-insulating layer 152 among the touch buffer layer 151 and the touch interlayer-insulating layer 152.

Due to the auxiliary opening AOP, cracks of the touch buffer layer 151 and the touch interlayer-insulating layer 152 disposed on the planarization layer 124 around the first sub-opening SBOP1 may be effectively prevented from spreading to the data output pad DOPD.

As shown in FIG. 14, in the second direction DR2 in which the first side SD1 and the second side SD2 face each other, a gap G6 between the auxiliary opening AOP and the planarization layer 124 may be smaller than a gap G7 between the auxiliary opening AOP and the first side SD1.

In this way, during the mounting process of the display driving circuit 200, high-temperature and high-pressure stress may be effectively prevented from being concentrated in the auxiliary opening AOP.

The display device 100 of one embodiment shown in FIG. 15 is substantially the same as the embodiments shown in FIGS. 9 to 14 except that the planarization layer 124 does not include the third protrusion PRS3 (see FIG. 9) and the fourth protrusion PRS4 (see FIG. 9), so that the redundant description will be omitted below.

In accordance with one embodiment of FIG. 15, the second sub-opening SBOP2 may extend from the third side SD3 and may be in contact with the first protrusion PRS1.

Further, the third sub-opening SBOP3 may extend from the fourth side SD4 and may be in contact with the second protrusion PRS2.

In this way, the inorganic insulating layers of the circuit layer 120 may be protected by the planarization layer 124 around the second side SD2, and the display driving circuit 200 (see FIG. 8) is spaced apart from the planarization layer 124 throughout the third side SD3 and the fourth side SD4, so that defects such as lifting defects or crack defects of the inorganic insulating layers of the circuit layer 120 may be further reduced.

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a substrate comprising a display area in which emission areas are arranged and a non-display area disposed around the display area;
a circuit layer disposed on the substrate;
an element layer disposed on the circuit layer;
an encapsulation layer disposed on the element layer;
a touch sensor layer disposed on the encapsulation layer; and
a display driving circuit mounted in a part of the non-display area of the substrate,
wherein the circuit layer comprises:
a gate insulating layer disposed on the substrate;
an interlayer-insulating layer disposed on the gate insulating layer; and
a planarization layer disposed on the interlayer-insulating layer;
wherein the circuit layer defines a first opening overlapping the display driving circuit in a plan view and penetrating the planarization layer, and
the first opening comprises a main opening overlapping the display driving circuit, and a first sub-opening extending from a first side, facing the display area, of an edge of the main opening.

2. The display device of claim 1, wherein a minimum gap between the planarization layer and each of vertices where two sides, extending in different directions, of the edge of the main opening are connected is smaller than a minimum gap between the first side of the main opening and the planarization layer in the plan view.

3. The display device of claim 2, wherein the edge of the main opening further comprises a second side facing the first side; and a third side and a fourth side connected between the first side and the second side and facing each other, and
the planarization layer comprises a first protrusion adjacent to a first vertex between the first side and the third side; and a second protrusion adjacent to a second vertex between the first side and the fourth side.

4. The display device of claim 3, wherein the planarization layer further comprises a third protrusion disposed adjacent to a part of the third side and a third vertex between the second side and the third side; and a fourth protrusion disposed adjacent to a part of the fourth side and a fourth vertex between the second side and the fourth side.

5. The display device of claim 4, wherein the first opening further comprises a second sub-opening extending from another part of the third side and in contact with the first protrusion and the third protrusion; and a third sub-opening extending from another part of the fourth side and in contact with the second protrusion and the fourth protrusion.

6. The display device of claim 4, wherein in each of the first protrusion, the second protrusion, the third protrusion, and the fourth protrusion, one side facing the main opening has an arc shape.

7. The display device of claim 3, wherein the first opening further comprises a second sub-opening extending from the third side and in contact with the first protrusion; and a third sub-opening extending from the fourth side and in contact with the second protrusion.

8. The display device of claim 3, further comprising a circuit board disposed adjacent to the display driving circuit in the plan view and bonded to an edge of the substrate,
wherein the circuit layer further comprises:
circuit bonding pads arranged in the main opening and to which the display driving circuit is bonded;
circuit connection lines electrically connected to the circuit bonding pads, respectively; and
substrate bonding pads arranged side by side on one side of the edge of the substrate adjacent to the circuit bonding pads and to which the circuit board is connected,
wherein the circuit bonding pads comprise:
data output pads disposed adjacent to the first side; and
data input pads disposed adjacent to the second side, and the circuit connection lines comprise:
data supply lines electrically connected to the data output pads, overlapping the first sub-opening, and extending to an edge of the display area; and
data pad lines electrically connected to the data input pads and extending to some of the substrate bonding pads.

9. The display device of claim 8, wherein in a direction in which the first side and the second side face each other, a gap between the first side and the planarization layer is greater than a gap between the second side and the planarization layer due to a width of the first sub-opening.

10. The display device of claim 9, wherein in the direction in which the first side and the second side face each other, the gap between the first side and the planarization layer is within a range from 50 micrometers (μm) to 100 μm.

11. The display device of claim 9, wherein the planarization layer comprises a first planarization layer disposed on the interlayer-insulating layer; and a second planarization layer covering the first planarization layer,
the second planarization layer comprises a first step portion disposed with a first thickness on the first planarization layer, a bottom extension portion facing the first side and in contact with the interlayer-insulating layer, and a second step portion disposed between the first step portion and the bottom extension portion,
a part of the second step portion adjacent to the first step portion is disposed on the first planarization layer with a second thickness smaller than the first thickness, and
in the direction in which the first side and the second side face each other, a part of the second step portion of the second planarization layer facing the first side is disposed with a width greater than the gap between the first side and the planarization layer.

12. The display device of claim 11, wherein the touch sensor layer comprises a touch buffer layer disposed on the encapsulation layer; a touch interlayer-insulating layer disposed on the touch buffer layer; and a touch planarization layer disposed on the touch interlayer-insulating layer, and
the touch planarization layer overlaps the first step portion in the plan view.

13. The display device of claim 8, wherein the touch sensor layer comprises a touch buffer layer disposed on the encapsulation layer; and a touch interlayer-insulating layer disposed on the touch buffer layer,
the circuit layer further comprises a lighting circuit overlapping the display driving circuit, surrounded by the main opening, disposed between the data output pads and the data input pads, and covered with the planarization layer, and
the lighting circuit is electrically connected to at least some of the data output pads.

14. The display device of claim 13, wherein each of the gate insulating layer, the interlayer-insulating layer, the touch buffer layer, and the touch interlayer-insulating layer contains an inorganic insulating material,
the planarization layer contains an organic insulating material, and
the touch buffer layer overlaps the lighting circuit and is in contact with the interlayer-insulating layer in the first opening.

15. The display device of claim 14, wherein the circuit layer further defines:
a second opening located between the data output pads and the lighting circuit in a direction in which the first side and the second side face each other, extending side by side with the first side, and penetrating at least the touch interlayer-insulating layer among the touch buffer layer and the touch interlayer-insulating layer; and
a third opening located between the data input pads and the lighting circuit in the direction in which the first side and the second side face each other, extending side by side with the second side, and penetrating at least the touch interlayer-insulating layer among the touch buffer layer and the touch interlayer-insulating layer.

16. The display device of claim 14, wherein the circuit layer further defines an auxiliary opening located within the first sub-opening, extending side by side with the first side, and penetrating at least the touch interlayer-insulating layer among the touch buffer layer and the touch interlayer-insulating layer, and
in a direction in which the first side and the second side face each other, a gap between the auxiliary opening and the planarization layer is smaller than a gap between the auxiliary opening and the first side.

17. A display device comprising:
a substrate comprising a display area in which emission areas are arranged and a non-display area disposed around the display area;
a circuit layer disposed on the substrate;
an element layer disposed on the circuit layer;
an encapsulation layer disposed on the element layer;
a touch sensor layer disposed on the encapsulation layer; and
a display driving circuit mounted in a part of the non-display area of the substrate,
wherein the circuit layer comprises:
a gate insulating layer disposed on the substrate;
an interlayer-insulating layer disposed on the gate insulating layer; and
a planarization layer disposed on the interlayer-insulating layer;
wherein the circuit layer defines a first opening overlapping the display driving circuit in a plan view and penetrating the planarization layer,
the first opening comprises a main opening overlapping the display driving circuit, and a first sub-opening extending from a first side, facing the display area, of an edge of the main opening,
the edge of the main opening further comprises a second side facing the first side; and a third side and a fourth side connected between the first side and the second side and facing each other, and
the planarization layer comprises a first protrusion adjacent to a first vertex between the first side and the third side; and a second protrusion adjacent to a second vertex between the first side and the fourth side.

18. The display device of claim 17, wherein a minimum gap between the first vertex and the planarization layer is smaller than a minimum gap between the first side and the planarization layer, and
a minimum gap between the second vertex and the planarization layer is smaller than the minimum gap between the first side and the planarization layer.

19. The display device of claim 18, further comprising a circuit board disposed adjacent to the display driving circuit in the plan view and bonded to an edge of the substrate.
wherein the circuit layer further comprises:
circuit bonding pads arranged in the main opening and to which the display driving circuit is bonded;
circuit connection lines electrically connected to the circuit bonding pads, respectively; and
substrate bonding pads arranged side by side on one side of the edge of the substrate adjacent to the circuit bonding pads and to which the circuit board is connected,
wherein the circuit bonding pads comprise:
data output pads disposed adjacent to the first side; and
data input pads disposed adjacent to the second side, the circuit connection lines comprise:
data supply lines electrically connected to the data output pads, overlapping the first sub-opening, and extending to an edge of the display area; and
data pad lines electrically connected to the data input pads and extending to some of the substrate bonding pads,
wherein the touch sensor layer comprises a touch buffer layer disposed on the encapsulation layer; and a touch interlayer-insulating layer disposed on the touch buffer layer,
the circuit layer further comprises a lighting circuit overlapping the display driving circuit, surrounded by the main opening, disposed between the data output pads and the data input pads, and covered with the planarization layer,
the lighting circuit is electrically connected to at least some of the data output pads,
each of the gate insulating layer, the interlayer-insulating layer, the touch buffer layer, and the touch interlayer-insulating layer contains an inorganic insulating material,
the planarization layer contains an organic insulating material,
the touch buffer layer overlaps the lighting circuit and is in contact with the interlayer-insulating layer in the first opening, and
the circuit layer further defines:
a second opening located between the data output pads and the lighting circuit in a direction in which the first side and the second side face each other, extending side by side with the first side, and penetrating at least the touch interlayer-insulating layer among the touch buffer layer and the touch interlayer-insulating layer; and
a third opening located between the data input pads and the lighting circuit in the direction in which the first side and the second side face each other, extending side by side with the second side, and penetrating at least the touch interlayer-insulating layer among the touch buffer layer and the touch interlayer-insulating layer.

20. The display device of claim 19, wherein the circuit layer further defines an auxiliary opening located within the first sub-opening, extending side by side with the first side, and penetrating at least the touch interlayer-insulating layer among the touch buffer layer and the touch interlayer-insulating layer, and
in the direction in which the first side and the second side face each other, a gap between the auxiliary opening and the planarization layer is smaller than a gap between the auxiliary opening and the first side.
